(19) United States
(12) Patent Application Publication
(10) Pub. No.: US 2009/0151910 A1
(43) Pub. Date: Jun. 18, 2009

(54) COMBINATION RACK SYSTEM FOR DISCHARGING HOT AIR SEPARATELY, AND SYSTEM AND METHOD FOR COOLING DATA CENTER USING THE COMBINATION RACK SYSTEM

(75) Inventors: Won-Ok Kwon, Daejeon (KR); Seong-Woon Kim, Daejeon (KR)

Correspondence Address: STAAS & HALSEY LLP, SUITE 700, 1201 NEW YORK AVENUE, N.W., WASHINGTON, DC, 20005, US

(73) Assignee: ELECTRONICS AND TELECOMMUNICATIONS RESEARCH INSTITUTE, Daejeon (KR)

(21) Appl. No.: 12/185,262

(22) Filed: Aug. 4, 2008

(30) Foreign Application Priority Data
Dec. 17, 2007 (KR) 10-2007-132576

(51) Int. Cl. H01L 23/467; H05K 7/18; H05K 7/20; H05K 5/00; F24H 3/02; F28D 15/00

(52) U.S. Cl. 165/121; 361/695; 165/104.34; 454/184

(57) ABSTRACT

Provided are a combination rack system for discharging hot air separately, and system and method for cooling a data center. The cooling system includes a combination rack system, a discharge pipe connected to the combination rack system, a docking part for connecting the combination rack system and the discharge pipe, a discharge fan for discharging air from the combination rack system to the discharge pipe, an inlet at one side of the discharge pipe for introducing outside air into the discharge pipe, and an outlet at the other side of the discharge pipe for discharging air from the discharge pipe. The combination rack system includes racks and cooling fans. The racks are spaced with their rear sides facing each other, and the cooling fans are disposed between the racks. Therefore, air heated in the combination rack system can be discharged from the combination rack system separately from inner cold air.

### CROSS-REFERENCE TO RELATED APPLICATIONS

This application claims priority under 35 U.S.C. §119 to Korean Patent Application No. 10-2007-132576, filed on Dec. 17. 2007, the disclosure of which is incorporated herein by reference in its entirety.

### BACKGROUND OF THE INVENTION

1. Field of the Invention

The present disclosure relates to a combination rack system for discharging hot air separately, and a system and method for cooling a data center using the combination rack system, and more particularly, to a combination rack system for discharging hot air separate from inner cold air for efficient cooling, and a system and method for cooling a data center using the combination rack system.

This work was supported by the IT R&D program of MIC/IITA [2007-S-016-01, A Development of Cost Effective and Large Scale Global Internet Service Solution]

2. Description of the Related Art

Recently, rack mounts are used to accommodate and install information processing devices such as servers and construct information processing systems. In a rack mount system, devices are stacked by placing the devices in standardized rack cabinets. That is, desired devices can be easily placed at desired positions. Therefore, systems can be flexibly configured and easily expanded using a small area.

Current large-scale data centers have problems related to power supply. Since more devices such as servers are accommodated in a rack, power consumption per unit area increases. Therefore, a heating, ventilating, and air conditioning (HVAC) apparatus consumes more power for cooling the servers densely accommodated in the rack.

FIG. 1 is a schematic view illustrating a rack system in which rack mount servers are mounted according to the related art. Air cooled by a cooling device is fed to a front side of a rack 100, and air heated by servers in the rack 100 is discharged through a rear side of the rack 100. Therefore, a hot spot exists at the rear side of the rack 100. Hot air moves upward from the hot spot and collides with a ceiling surface. In this way, the hot air flows to other places. Therefore, it takes a large amount of power to cool the distributed hot air, and the power consumption occupies a significant portion of power consumption of a data center.

### SUMMARY

Therefore, an object of the present invention is to provide a combination rack system for discharging hot air separate from inner cold air for efficient cooling, and a system and method for cooling a data center using the combination rack system.

To achieve these and other advantages and in accordance with the purpose(s) of the present invention as embodied and broadly described herein, a combination rack system for discharging hot air separately in accordance with an aspect of the present invention includes: first and second racks spaced a predetermined distance apart from each other with rear sides of the first and second racks facing each other; a plurality of cooling fans disposed at lower, middle, and upper positions between the first and second racks; and a link part for connecting the spaced first and second racks.

The first and second racks may include blank masks, mount servers, mount disk devices, mount switches, and cooling fan blanks. Each of the cooling fans may be insertable into the cooling fan blank of the first rack or the second rack.

To achieve these and other advantages and in accordance with the purpose(s) of the present invention, a cooling system of a data center in accordance with another aspect of the present invention includes: a combination rack system including first and second racks and a plurality of cooling fans, the first and second racks being spaced apart from each other with rear sides of the first and second racks facing each other, the cooling fans being disposed between the spaced first and second racks; a discharge pipe connected to an upper portion of the combination rack system; a docking part for connecting the combination rack system and the discharge pipe; a discharge fan disposed between the discharge pipe and the docking part for discharging air from the combination rack system to the discharge pipe; an inlet disposed at one side of the discharge pipe for introducing outside air into the discharge pipe; and an outlet disposed at the other side of the discharge pipe for discharging air from the discharge pipe.

The docking unit may be adjustable in length for connecting the combination rack system and the discharge pipe.

To achieve these and other advantages and in accordance with the purpose(s) of the present invention, a method for cooling a data center in accordance with another aspect of the present invention includes: discharging hot air generated from a combination rack system in which rear sides of racks face each other; directing the hot air discharged from the combination rack system to a discharge pipe; and introducing outside air into the discharge pipe through one side of the discharge pipe to discharge the hot air from the discharge pipe through the other side of the discharge pipe using the introduced outside air.

The combination rack system may be separatable into first and second rack systems, and the first and second rack systems may be movable. The first and second rack systems may be hermetically coupled to each other.

The foregoing and other objects, features, aspects and advantages of the present invention will become more apparent from the following detailed description of the present invention when taken in conjunction with the accompanying drawings.

### BRIEF DESCRIPTION OF THE DRAWINGS

The accompanying drawings, which are included to provide a further understanding of the invention and are incorporated in and constitute a part of this specification, illustrate embodiments of the invention and together with the description serve to explain the principles of the invention.

FIG. 1 is a schematic view illustrating a rack system in which rack mount servers are mounted according to the related art;

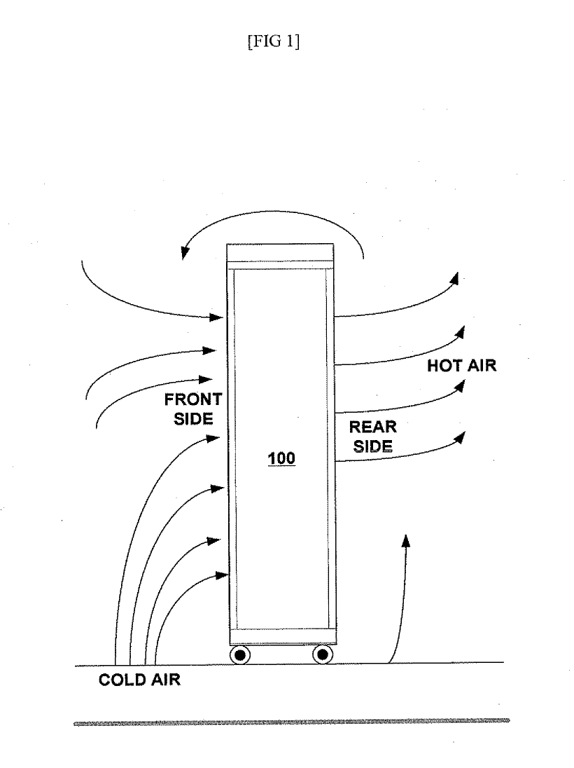

FIG. 2 is a schematic view illustrating a combination rack system according to an embodiment of the present invention;

FIG. 3 is a schematic view illustrating front sides of racks of the combination rack system according to an embodiment of the present invention;

FIG. 4 is a schematic view illustrating lateral sides of the racks of the combination rack system according to an embodiment of the present invention;

FIG. 5 is a schematic view illustrating a cooling system of a rack data center according to an embodiment of the present invention;

FIG. 6 is a schematic view illustrating a rack data center including a cooling system; and

FIG. 7 is a flowchart for explaining a method of cooling a rack data center according to an embodiment of the present invention.

### DETAILED DESCRIPTION OF EMBODIMENTS

Hereinafter, specific embodiments will be described in detail with reference to the accompanying drawings. The invention may, however, be embodied in many different forms and should not be construed as being limited to the embodiments set forth herein.

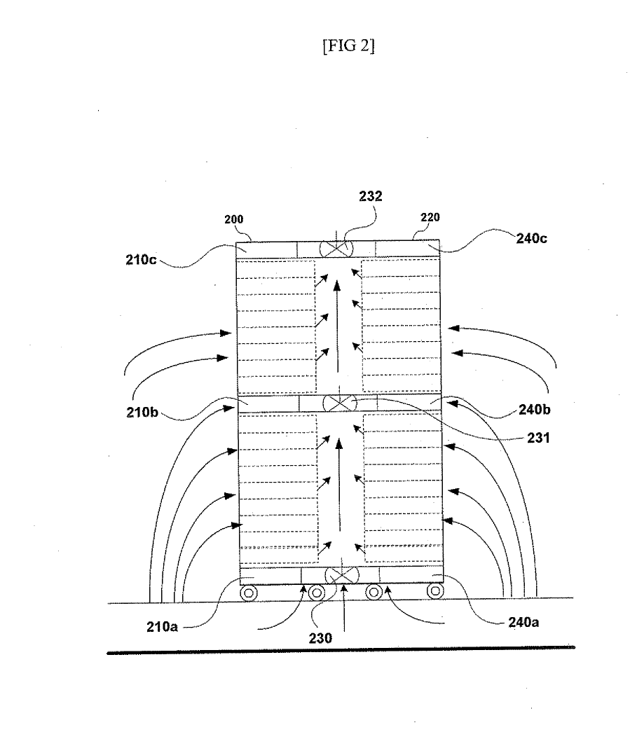

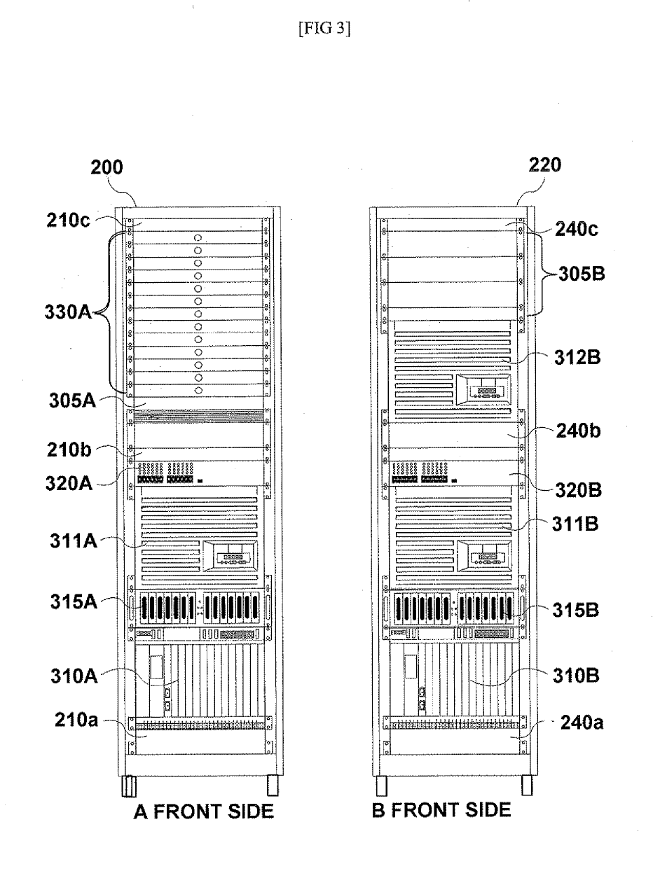

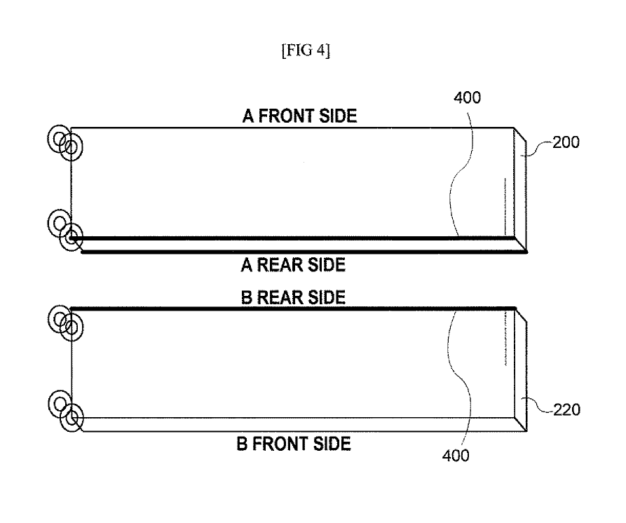

FIG. 2 is a schematic view illustrating a combination rack system according to an embodiment of the present invention, FIG. 3 is a schematic view illustrating front sides of racks of the combination rack system according to an embodiment of the present invention, and FIG. 4 is a schematic view illustrating lateral sides of the racks of the combination rack system according to an embodiment of the present invention.

The combination rack system of the present invention will now be described in detail with reference to FIGS. 2 through 4.

Referring to FIG. 2, the combination rack system of the present invention includes a first rack 200, a second rack 220, a plurality of cooling fans 230, 231, and 232, and link parts 400. The first and second racks 200 and 220 have the same structure and are spaced a predetermined distance apart from each other with their rear sides facing each other. The cooling fans 230, 231, and 232 are disposed at lower, middle, and upper positions between the spaced first and second racks 200 and 220. The link parts 400 are used to connect the first and second racks 200 and 220 and cover a gap between the first and second racks 200 and 220.

Referring to FIG. 3, the first and second racks 200 and 220 have the same structure. The first and second racks 200 and 220 include blank masks 305A and 3051B, mount servers 310A, 311A, 3101B, 31113, and 312B, mount disk devices 315A and 315B, mount switches 320A and 320B, and cooling fan blanks 210a, 210b, 210c, 240a, 240b, and 240c.

The blank masks 305A and 305B are disposed at empty slots of the second racks 200 and 220 to block outside air and prevent outflows of air heated by the mount servers 310A, 311A, 31013, 31113, and 312B from flowing outward.

The mount servers 310A, 311A, 310B, 311B, and 31213, the mount disk devices 315A and 315B, and the mount switches 320A and 320B are mounted in slots of the second racks 200 and 220. The mount switches 320A and 320B include cabling terminals and power terminals at front and rear sides of the second racks 200 and 220.

The cooling fan blanks 210a, 210b, 210c, 240a, 240b, and 240c of the second racks 200 and 220 are empty slots configured to accommodate the cooling fans 230, 231, and 232 when the second racks 200 and 220 are separated.

Referring to FIG. 4, the link parts 400 are configured to connect and disconnect the second racks 200 and 220. For example, the link parts 400 can include rubber packings. The link parts 400 can be detachably attached to the rear sides of the second racks 200 and 220 and have guide structures for easily connecting, sealing, and disconnecting the second racks 200 and 220.

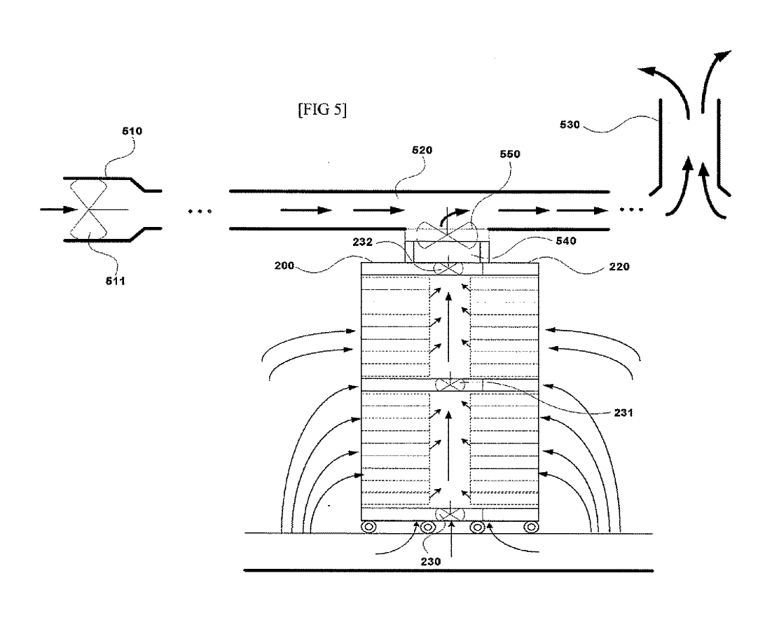

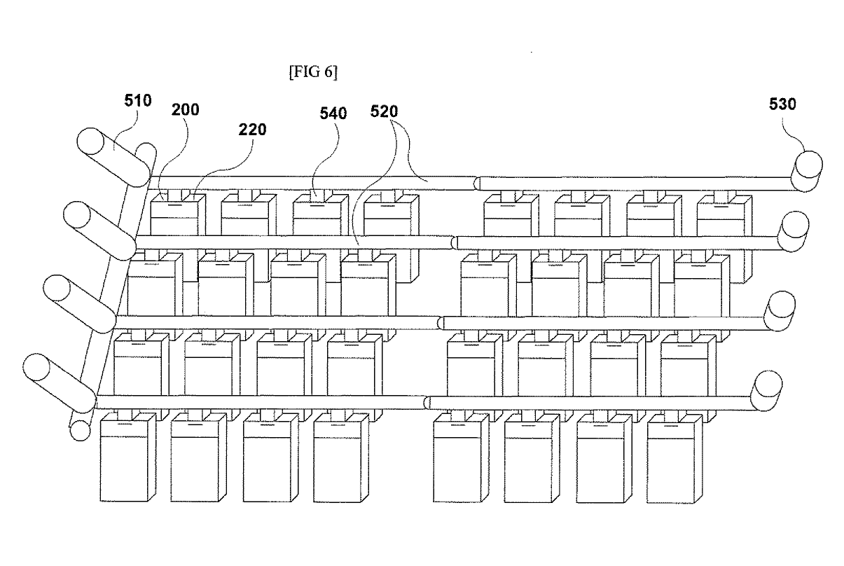

FIG. 5 is a schematic view illustrating a cooling system of a rack data center according to an embodiment of the present invention, and FIG. 6 is a schematic view illustrating a rack data center including a cooling system. Referring to FIG. 5, the cooling system of the rack data center includes a combination rack system, a discharge pipe 520, a docking part 540, a discharge fan 550, an inlet 510, and an outlet 530. The combination rack system includes first and second racks 200 and 220, and cooling fans 230, 231, and 232. The second racks 200 and 220 are spaced a predetermined distance apart from each other with their rear sides facing each other, and the cooling fans 230, 231, and 232 are disposed between the spaced second racks 200 and 220. The discharge pipe 520 is connected to an upper portion of the combination rack system. The docking part 540 connects the combination rack system and the discharge pipe 520. The discharge fan 550 is disposed between the discharge pipe 520 and the docking part 540 for discharging air from the combination rack system to the discharge pipe 520. The inlet 510 is connected to one side of the discharge pipe 520 for introducing outside air, and the outlet 530 is connected to the other side of the discharge pipe 520 for discharging inside air. The rack data center includes a plurality of combination rack systems such as the combination rack system shown in FIG. 5.

The second racks 200 and 220 of the combination rack system are spaced a predetermined distance apart from each other with their rear sides facing each other and are connected through link parts 400.

Here, the cooling fans 230, 231, and 232 are disposed at a gap between the second racks 200 and 220.

In detail, the cooling fans 230, 231, and 232 are disposed at lower, middle, and upper positions between the second racks 200 and 220, respectively. The cooling fans 230, 231, and 232 are used to force air heated at the rear sides of the second racks 200 and 220 to flow upward. The cooling fan 230 forces relatively cold air of the lower position to flow upward. The cooling fan 231 blows hot air upward, and the cooling fan 232 blows the hot air to the discharge pipe 520.

Air cooled by an additional cooling system can be fed to a lower side of the combination rack system.

The second racks 200 and 220 of the combination rack system can be disconnected and moved apart for repair works such as cable repairing. The second racks 200 and 220 are interchangeable.

The discharge pipe 520 is connected to a plurality of combination rack systems of the rack data center to receive hot air discharged from the combination rack systems and discharge the hot air to an outside area. A plurality of discharge pipes can be provided, and a plurality of combination rack systems can be connected to one discharge pipe.

The docking part 540 is used to hermitically connect the combination rack system and the discharge pipe 520. The length of the docking part 540 can be adjustable according to connection conditions. That is, although the distance between the combination rack system and the discharge pipe 520 is varied, the combination rack system and the discharge pipe 520 can be connected by adjusting the length of the docking part 540.

An inlet fan 511 is disposed in the inlet 510 connected to one side of the discharge pipe 520 to introduce outside air. That is, since outside air is intruded by the inlet fan 511, hot air can smoothly flow in the discharge pipe 520.

The outlet 530 is connected to the other side of the discharge pipe 520 to discharge hot air from the discharge pipe 520. That is, hot air generated in the combination rack system can be smoothly discharged through the outlet 530 of the discharge pipe 520 owing to outside air introduced into the discharge pipe 520 by the inlet fan 511.

Since the cooling system is configured to discharge air heated in the rack data center to the outside of the rack data center, the cooling system can have high cooling efficiency.

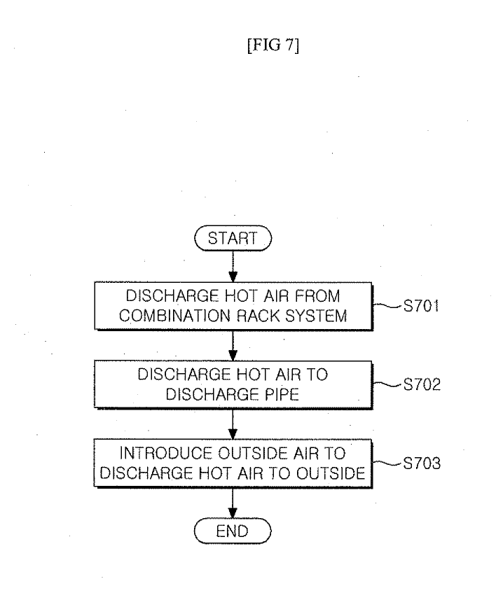

FIG. 7 is a flowchart for explaining a method of cooling a rack data center according to an embodiment of the present invention. Referring to FIG. 7, air heated in a combination rack system in which rear sides of racks face each other is discharged in operation S701. Air introduced into the combination rack system through a front or lower side of the combination rack system is heated by servers disposed in the combination rack system and is upwardly discharged by a cooling fan. The racks of the combination rack system are hermetically coupled in order to prevent leakage of hot air flowing in a passage between the racks, and blank masks are disposed at empty slots of the combination rack system to prevent outflows of hot air.

In operation S702, heated air discharged from the combination rack system is directed to a discharge pipe. The combination rack system and the discharge pipe are connected by a docking structure to prevent inflow of outside air. A discharge fan is disposed between the combination rack system and the discharge pipe for smoothly discharging hot air from the combination rack system to the discharge pipe.

In operation S703, outside air is introduced into the discharge pipe through one side of the discharge pipe, and hot air discharged from the combination rack system to the discharge pipe is discharged through the other side of the discharge pipe using the outside air introduced through the other side of the discharge pipe.

In detail, an inlet is formed at one side of the discharge pip, and an inlet fan is disposed at the inlet to introduce outside air into the discharge pip. Hot air discharged from the combination rack system to the discharge pip is discharged from the discharge pip using flows of the outside air introduced through the inlet. In the rack data center, a plurality of combination rack systems may be connected to the discharge pip. Hot air discharged from the combination rack systems are discharged from the rack data center through the discharge pip.

In this way, air heated by the servers of the combination rack system is discharged to an outside area through the discharge pip, and only cold air is introduced into the combination rack system. Therefore, cooling efficiency can be improved, and thus cooling costs can be reduced.

According to the combination rack system for discharging hot air separately, and the system and method for cooling a data center using the combination rack system, air heated in the combination rack system can be discharged separate from inner cold air so that cooling efficiency can be improved.

Furthermore, when a data center uses the combination rack system, the area of the data center can be efficiently used.

In addition, the cooling efficiency of the data center can be improved, and thus the cooling costs of the data center can be reduced.

As the present invention may be embodied in several forms without departing from the spirit or essential characteristics thereof, it should also be understood that the above-described embodiments are not limited by any of the details of the foregoing description, unless otherwise specified, but rather should be construed broadly within its spirit and scope as defined in the appended claims, and therefore all changes and modifications that fall within the metes and bounds of the claims, or equivalents of such metes and bounds are therefore intended to be embraced by the appended claims.

What is claimed is:

1. A combination rack system for discharging hot air separately, comprising:
first and second racks spaced a predetermined distance apart from each other with rear sides of the first and second racks facing each other;
a plurality of cooling fans disposed at lower, middle, and upper positions between the first and second racks; and
a link part for connecting the spaced first and second racks.

2. The combination rack system of claim 1, wherein the first and second racks comprise blank masks, mount servers, mount disk devices, mount switches, and cooling fan blanks.

3. The combination rack system of claim 2, wherein each of the cooling fans is insertable into the cooling fan blank of the first rack or the second rack.

4. The combination rack system of claim 1, wherein the blank masks are inserted in blank slots of the first and second racks for blocking outside air.

5. The combination rack system of claim 1, wherein the link part is detachably attached to the first and second racks.

6. The combination rack system of claim 5, wherein the link part is detachably attached to the first and second racks using a rubber packing.

7. The combination rack system of claim 1, farther comprising a cabling terminal and a power terminal respectively disposed at front and rear sides of each of the first and second racks.

8. A cooling system of a data center, comprising
a combination rack system comprising first and second racks and a plurality of cooling fans, the first and second racks being spaced apart from each other with rear sides of the first and second racks facing each other, the cooling fans being disposed between the spaced first and second racks;
a discharge pipe connected to an upper portion of the combination rack system;
a docking part for connecting the combination rack system and the discharge pipe;
a discharge fan disposed between the discharge pipe and the docking part for discharging air from the combination rack system to the discharge pipe;
an inlet disposed at one side of the discharge pipe for introducing outside air into the discharge pipe; and
an outlet disposed at the other side of the discharge pipe for discharging air from the discharge pipe.

9. The cooling system of claim 8, further comprising an inlet fan disposed at the inlet for introducing outside air into the discharge pipe.

10. The cooling system of claim 8, wherein the combination rack system further comprises a link part for connecting the first and second racks.

11. The cooling system of claim 8, wherein the cooling fans of the combination rack system are disposed at lower, middle, and upper positions.

12. The cooling system of claim 8, wherein the docking unit is adjustable in length for connecting the combination rack system and the discharge pipe.

13. A method for cooling a data center, comprising:
discharging hot air generated from a combination rack system in which rear sides of racks face each other;
directing the hot air discharged from the combination rack system to a discharge pipe; and
introducing outside air into the discharge pipe through one side of the discharge pipe to discharge the hot air from the discharge pipe through the other side of the discharge pipe using the introduced outside air.

14. The method of claim 13, wherein a plurality of combination rack systems is connected to the discharge pipe.

15. The method of claim 13, wherein the combination rack system is separatable into first and second rack systems, and the first and second rack systems are movable.

16. The method of claim 15, wherein the first and second rack systems are hermetically coupled to each other.
